(19) United States
(12) Patent Application Publication
(10) Pub. No.: US 2016/0062168 A1
(43) Pub. Date: Mar. 3, 2016

(54) Display device and thin-film transistor substrate and method for producing same

(71) Applicant: Sharp Kabushiki Kaisha, Osaka (JP)

(72) Inventors: Yasumori FUKUSHIMA, Osaka-shi (JP); Noriko WATANABE, Osaka-shi (JP); Kenji MISONO, Osaka-shi (JP); Masaki FUJIWARA, Osaka-shi (JP)

(21) Appl. No.: 14/938,918

(22) Filed: Nov. 12, 2015

Related U.S. Application Data
(62) Division of application No. 13/994,774, filed on Jun. 17, 2013.

(30) Foreign Application Priority Data
Dec. 21, 2010 (JP) 2010-284109

(51) Int. Cl. G02F 1/13363; H01L 29/786; H01L 27/12; G02F 1/1368; G02F 1/1333

(52) U.S. Cl. CPC G02F 1/13363; G02F 1/1368; G02F 1/133305; H01L 27/1222; H01L 29/78669

(57) ABSTRACT

A display device includes a TFT substrate (30) containing a transparent first resin substrate (11) having the heat resistance and a plurality of TFTs (5) disposed on the first resin substrate (11) and a counter-substrate (50) containing a transparent second resin substrate (41) having the heat resistance and being disposed opposing to the TFT substrate (30), wherein the first resin substrate (11) and the second resin substrate (41) have a thickness of 5 μm or more and 20 μm or less and a birefringence of 0.002 or more and 0.1 or less.

### TECHNICAL FIELD

The present invention relates to a display device and a thin film transistor substrate and a manufacturing method therefor. In particular, the present invention relates to a display device of an electronic book, an electronic notebook, an electronic newspaper, an electronic signboard (digital signage), or the like, and a thin film transistor substrate and a manufacturing method therefor.

### BACKGROUND ART

A liquid crystal display panel constituting a liquid crystal display device includes, for example, a TFT substrate provided with a thin film transistor (hereafter may be referred to as “TFT”), a pixel electrode, and the like on a subpixel serving as a minimum unit of an image basis, a counter-substrate which is disposed opposing to the TFT substrate and which is provided with a common electrode and the like, and a liquid crystal layer sealed in between the TFT substrate and the counter-substrate.

As for display devices, e.g., liquid crystal display devices, in recent years, a display panel including a resin substrate instead of a glass substrate, which has been used previously, has been proposed.

For example, PTL 1 discloses a display device including a display panel in which a first substrate and a second substrate are disposed opposing to each other, wherein the first substrate includes an insulating substrate made of a resin, a circuit layer having a circuit in which a plurality of TFT elements are disposed in the matrix, and a polarizer disposed between the insulating substrate and the circuit layer, and the insulating substrate has a thickness of 20 μm or more and 150 μm or less, a transmittance of 80% or more with respect to visible light with a wavelength of 400 nm or more and 800 nm or less, a 3% weight loss temperature of 300° C. or higher, and no melting point or a melting point of 300° C. or higher. In addition, PTL 1 mentions that according to this, a display device including a polarizer, e.g., a liquid crystal display device, can be made still thinner and lighter.

### CITATION LIST

### Patent Literature

PTL 1: Japanese Unexamined Patent Application Publication No. 2010-32768

### SUMMARY OF INVENTION

### Technical Problem

Meanwhile, in formation of a TFT by using amorphous silicon on a substrate, a step to form an insulating film and a semiconductor film at 300° C. or higher is performed. Therefore, a resin substrate made of, for example, polyimide having high heat resistance is suitable for the substrate to be provided with the TFT. Then, for example, the polyimide resin substrate can be formed by applying a solution in which polyamic acid serving as a precursor of polyimide is dissolved in an organic solvent, e.g., dimethylacetamide or N-methylpyrrolidone, to the surface of a support substrate, e.g., a glass substrate, and thereafter, volatilizing the organic solvent and inducing an imidization reaction through heating of the support substrate. In this regard, for example, after the TFT and the like are formed on the polyimide resin substrate, which has been formed on the support substrate, that is, on a film-forming surface, the resin substrate can be separated from the support substrate by applying laser light from the back of the support substrate taking advantage of an ablation phenomenon due to the laser light. Then, as for the resin substrate formed by such a method, the film-forming surface is made into an uneven shape easily. Therefore, display variations occur in a display device including the resin substrate, so that the quality of display may be degraded. The cause of formation of this uneven surface (film-forming surface) of the resin substrate is estimated that in a step to volatilize the organic solvent, the organic solvent is vaporized from the coating film surface by heat energy obtained through heating of the support substrate and, at the same time, the organic solvent is also vaporized in the inside of the coating film. Specifically, the solution, in which the above-described polyamic acid has been dissolved, has relatively high viscosity and, thereby, bubbles of the organic solvent vaporized in the inside of the coating film take time to reach the coating film surface. In this regard, as the coating film becomes thicker, the time required to reach the above-described coating film surface increases. Consequently, as the coating film surface is approached, bubbles of the organic solvent snowball and it is believed that the proportion of bubbles increases in the vicinity of the coating film surface. That is, if the thickness of the coating film becomes more than or equal to a predetermined film thickness, the upward movement speed of the bubbles of the organic solvent volatilized in the inside of the coating film becomes larger than the speed of vaporization of the organic solvent from the coating film surface, and it is estimated that some type of boiling phenomenon occurs on the coating film surface and the surface of the resin substrate is formed taking on an uneven shape.

In addition, in formation of the TFT and the like on the resin substrate, before an insulating film, a semiconductor film, an electrically conductive film, and the like are formed, it is necessary to perform a step to wash the substrate surface for the purpose of removal of foreign matters and cleaning of the substrate surface. Consequently, it is necessary that the resin substrate have the resistance to a cleaning fluid, e.g., an organic solvent, (solvent resistance). In this regard, the polyimide is formed by imidization through the above-described polyamic acid on the basis of combinations of various types of tetracarboxylic acid dianhydride and various types of diamine. Therefore, it is possible to perform molecular design of polyimide having an optimum structure in accordance with the use, although it is difficult to synthesize a polyimide satisfying all the required characteristics. In particular, it is considered that the solvent resistance is in the relationship of trade-off with the transmittance, the birefringence, and the like, which contribute to the display quality to a great extent.

The present invention has been made in consideration of the above-described points, and the object thereof is to suppress surface unevenness of a resin substrate and, in addition, ensure the solvent resistance.

### Solution to Problem

In order to achieve the above-described object, in the present invention, the thickness of a resin substrate is specified to be 5 μm or more and 20 μm or less, and the birefringence of the resin substrate is specified to be 0.002 or more and 0.1 or less.

Specifically, a display device according to the present invention is characterized by including a thin film transistor substrate containing a transparent first resin substrate having the heat resistance and a plurality of thin film transistors disposed on the first resin substrate and a counter-substrate containing a transparent second resin substrate having the heat resistance and being disposed opposing to the above-described thin film transistor substrate, wherein the above-described first resin substrate and second resin substrate have a thickness of 5 μm or more and 20 μm or less and a birefringence of 0.002 or more and 0.1 or less.

According to the above-described configuration, the thickness of each of the first resin substrate disposed as a base substrate of the thin film transistor substrate and the second resin substrate disposed as a base substrate of the counter-substrate is 5 μm or more and 20 μm or less. Therefore, for example, generation of bubbles in coating films of a resin solution serving as the first resin substrate and the second resin substrate is suppressed when the organic solvent is volatilized and, thereby, surface unevenness of the first resin substrate and the second resin substrate is suppressed. Here, in the case where the thickness of each of the first resin substrate and the second resin substrate is larger than 20 μm, for example, even when the temperature in volatilization of the organic solvent is lowered to about room temperature to suppress generation of bubbles from the coating film, the surfaces of each of the first resin substrate and the second resin substrate is formed taking on an uneven shape. Meanwhile, in the case where the thickness of each of the first resin substrate and the second resin substrate is smaller than 5 μm, it becomes difficult that the first resin substrate and the second resin substrate maintain their shapes and, in addition, for example, when the first resin substrate and the second resin substrate are separated from their respective support substrates, e.g., glass substrates, used for forming the resin substrates, the first resin substrate and the second resin substrate in themselves are damaged and it becomes difficult to separate with good reproducibility.

Also, the birefringence of each of the first resin substrate and the second resin substrate is 0.002 or more and 0.1 or less, so that the solvent resistance of the first resin substrate and the second resin substrate is specifically ensured. Here, FIG. 9 is a graph showing the relationship between the birefringence and the film thickness decrease rate of the resin substrate. In this regard, the film thickness decrease rate indicated by the vertical axis in FIG. 9 is the decrease rate of a film thickness (substrate thickness) after the resin substrate is immersed in an organic solvent and serves as an indicator of the solvent resistance. Here, in general, the solvent resistance is in the relationship of trade-off with the birefringence. Therefore, various polyimide resin substrates were formed, the birefringence of each resin substrate was measured using, for example, Retardation Measurement System produced by OTSUKA ELECTRONICS CO., LTD., and in addition, each resin substrate was subjected to a treatment of immersion in an organic solvent (for example, a mixed solution of 2-aminoethanol and dimethyl sulfoxide (percent by weight ratio 70:30), a single solution of dimethyl sulfoxide, or the like) for about 1 hour at 60° C., the film thickness decrease rate was calculated from film thicknesses before and after the treatment of each resin substrate, and the relationship between the birefringence and the film thickness decrease rate of the resin substrate was derived (refer to black circles in the graph shown in FIG. 9). Then, in consideration of the practicality, it is believed that the resin substrate can be washed if the film thickness decrease rate of the solvent resistance is about 3% or less. The birefringence at that time is 0.002 or more in the region surrounded by a thick broken line shown in FIG. 9. In consideration of the practical limit of phase difference compensation, the upper limit thereof is 0.1 or less.

Consequently, in the case where the thickness of each of the first resin substrate and the second resin substrate is 5 μm or more and 20 μm or less and, in addition, the birefringence of each of the first resin substrate and the second resin substrate is 0.002 or more and 0.1 or less, surface unevenness is suppressed and, in addition, the solvent resistance is ensured with respect to the first resin substrate and the second resin substrate.

A polarizing film may be disposed on each of the outside surface of the above-described thin film transistor substrate and the outside surface of the above-described counter-substrate.

According to the above-described configuration, the polarizing film is attached to each of the outside surface of the thin film transistor substrate and the outside surface of the counter-substrate. Therefore, the thin film transistor substrate and the counter-substrate are reinforced by the strength of the polarizing films in themselves.

A vertical alignment liquid crystal layer may be sealed in between the above-described thin film transistor substrate and counter-substrate, and the above-described first resin substrate and second resin substrate may have a birefringence of 0.05 or more and 0.028 or less.

According to the above-described configuration, the vertical alignment liquid crystal layer sealed in between the thin film transistor substrate and the counter-substrate functions as a positive C plate (the refractive indices nₓ and n_{y} in the in-plane direction of the substrate are smaller than the refractive index n_{z} in the direction perpendicular to the substrate, that is, nₓ=n_{y}<n_{z}). Therefore, a phase difference due to the birefringence of the first resin substrate and the second resin substrate which function as negative C plates (the refractive indices nₓ and n_{y} in the in-plane direction of the substrate are larger than the refractive index n_{z} in the direction perpendicular to the substrate, that is, nₓ=n_{y}>n_{z}) is compensated without disposing a phase difference compensation film separately. Here, in order to obtain good display characteristics, it becomes necessary to compensate a phase difference of about 275 nm which is a phase difference corresponding to one-half the wavelength of green (550 nm) with the highest luminosity factor of a human in general. Then, if the assumption is made that the vertical alignment liquid crystal layer functioning as a positive C plate is compensated evenly by the first resin substrate on the thin film transistor substrate side and the second resin substrate on the counter-substrate side, each side may compensate a phase difference of 137.5 nm (=275 nm/2). However, the polarizing film attached to each of the outside surface of the thin film transistor substrate and the outside surface of the counter-substrate functions as the negative C plate. In consideration of the fact that a phase difference due to the birefringence of the polarizing film is about several nanometers to 30-odd nanometers, the amount of compensation of phase difference by each of the first resin substrate and the second resin substrate becomes about 100 nm to 137.5 nm. Then, on the basis of the relationship, Δn·d (film thickness)=phase difference, when the film thicknesses of the first resin substrate and the second resin substrate are 5 μm to 20 μm, the corresponding Δn (birefringence) becomes 0.005 to 0.027. Consequently, in the case where the birefringence is 0.005 to 0.027, the birefringence falls within the above-described range taking the solvent resistance into consideration (0.002 to 0.1), so that the solvent resistance is also ensured.

Phase difference compensation films may be disposed between the above-described thin film transistor substrate and the above-described polarizing film and between the above-described counter-substrate and the above-described polarizing film in order to compensate the birefringence of the above-described first resin substrate and the birefringence of the above-described second resin substrate, respectively.

According to the above-described configuration, a phase difference compensation film which functions as the positive C plate (the refractive indices nₓ and n_{y} in the in-plane direction of the substrate are smaller than the refractive index n_{z} in the direction perpendicular to the substrate, that is, nₓ=n_{y}<n_{z}) is disposed in each of between the thin film transistor substrate and the polarizing film and between the counter-substrate and the polarizing film. Therefore, (a phase difference due to) the birefringence of each of the first resin substrate and the second resin substrate which function as negative C plates (the refractive indices nₓ and n_{y} in the in-plane direction of the substrate are larger than the refractive index n_{z} in the direction perpendicular to the substrate, that is, nₓ=n_{y}>n_{z}) is compensated and, in addition, the thin film transistor substrate and the counter-substrate are further reinforced by the strength of the phase difference compensation films in themselves.

A liquid crystal layer may be sealed in between the above-described thin film transistor substrate and counter-substrate.

According to the above-described configuration, the liquid crystal layer is sealed in between the thin film transistor substrate and the counter-substrate. Therefore, a liquid crystal display device is specifically formed as a display device.

The above-described first resin substrate and second resin substrate may be made of polyimide.

According to the above-described configuration, the first resin substrate and the second resin substrate are made of polyimide. Therefore, the first resin substrate and the second resin substrate have specifically the heat resistance.

The above-described first resin substrate and second resin substrate may be made of alicyclic polyimide.

According to the above-described configuration, the first resin substrate and the second resin substrate are made of alicyclic polyimide and intramolecular and intermolecular charge-transfer complexes are not formed. Consequently, the transparency in the visible light region becomes good and colorless, transparent first resin substrate and second resin substrate are obtained.

The above-described first resin substrate and second resin substrate may be made of fluorinated aromatic polyimide.

According to the above-described configuration, the first resin substrate and the second resin substrate are made of fluorinated aromatic polyimide and intramolecular and intermolecular charge-transfer complexes are not formed because of a fluorine-containing structure. Consequently, the transparency in the visible light region becomes good and colorless, transparent first resin substrate and second resin substrate are obtained.

Meanwhile, a thin film transistor substrate according to the present invention is characterized by including a transparent resin substrate having the heat resistance and a plurality of thin film transistors disposed on the above-described resin substrate, wherein the above-described resin substrate has a thickness of 5 μm or more and 20 μm or less and a birefringence of 0.002 or more and 0.1 or less.

According to the above-described configuration, the thickness of the resin substrate disposed as a base substrate of the thin film transistor substrate is 5 μm or more and 20 μm or less. Therefore, for example, generation of bubbles in a coating film of a resin solution serving as the resin substrate is suppressed when the organic solvent is volatilized and, thereby, surface unevenness of the resin substrate is suppressed. Here, in the case where the thickness of the resin substrate is larger than 20 μm, for example, even when the temperature in volatilization of the organic solvent is lowered to about room temperature to suppress generation of bubbles from the coating film, the surface of the resin substrate is formed taking on an uneven shape. Meanwhile, in the case where the thickness of the resin substrate is smaller than 5 μm, it becomes difficult that the resin substrate maintains the shape thereof and, in addition, for example, when the resin substrate is separated from the support substrate, e.g., a glass substrate, used for forming the resin substrate, the substrate in itself of the resin substrate is damaged and it becomes difficult to separate with good reproducibility.

Also, the birefringence of the resin substrate is 0.002 or more and 0.1 or less, so that the solvent resistance of the resin substrate is specifically ensured. Here, FIG. 9 is a graph showing the relationship between the birefringence and the film thickness decrease rate of the resin substrate. In this regard, the film thickness decrease rate indicated by the vertical axis in FIG. 9 is the decrease rate of a film thickness (substrate thickness) after the resin substrate is immersed in an organic solvent and serves as an indicator of the solvent resistance. Here, in general, the solvent resistance is in the relationship of trade-off with the birefringence. Therefore, various polyimide resin substrates were formed, the birefringence of each resin substrate was measured using, for example, Retardation Measurement System produced by OTSUKA ELECTRONICS CO., LTD., and in addition, each resin substrate was subjected to a treatment of immersion in an organic solvent (for example, a mixed solution of 2-aminoethanol and dimethyl sulfoxide (percent by weight ratio 70:30), a single solution of dimethyl sulfoxide, or the like) for about 1 hour at 60° C., the film thickness decrease rate was calculated from film thicknesses before and after the treatment of each resin substrate, and the relationship between the birefringence and the film thickness decrease rate of the resin substrate was derived (refer to black circles in the graph shown in FIG. 9). Then, in consideration of the practicality, it is believed that the resin substrate can be washed if the film thickness decrease rate of the solvent resistance is about 3% or less. The birefringence at that time is 0.002 or more in the region surrounded by a thick broken line shown in FIG. 9. In consideration of the practical limit of phase difference compensation, the upper limit thereof is 0.1 or less.

Consequently, in the case where the thickness of the resin substrate is 5 μm or more and 20 μm or less and, in addition, the birefringence of the resin substrate is 0.002 or more and 0.1 or less, surface unevenness is suppressed and, in addition, the solvent resistance is ensured with respect to the resin substrate.

Meanwhile, a method for manufacturing a thin film transistor substrate, according to the present invention, is a method for manufacturing a thin film transistor substrate including a transparent resin substrate having the heat resistance and a plurality of thin film transistors disposed on the above-described resin substrate and is characterized by including the steps of forming a resin substrate having a thickness of 5 μm or more and 20 μm or less and a birefringence of 0.002 or more and 0.1 or less by supplying a resin solution to a support substrate and, thereafter, heating the support substrate so as to volatilize an organic solvent from the resin solution in a resin substrate formation step, forming each of the above-described thin film transistors on the above-described resulting resin substrate in a thin film transistor formation step, and separating the above-described support substrate from the resin substrate provided with each of the above-described thin film transistors in a separation step.

According to the above-described method, in the resin substrate formation step, the thickness of the resin substrate serving as a base substrate of the thin film transistor substrate is specified to be 5 μm or more and 20 μm or less. Therefore, generation of bubbles in coating film of a resin solution is suppressed when the organic solvent is volatilized and, thereby, surface unevenness of the resin substrate is suppressed. Here, in the case where the thickness of the resin substrate is larger than 20 μm, for example, even when the temperature in volatilization of the organic solvent is lowered to about room temperature to suppress generation of bubbles from the coating film, the surface of the resin substrate is formed taking on an uneven shape. Meanwhile, in the case where the thickness of the resin substrate is smaller than 5 μm, it becomes difficult that the resin substrate maintains the shape thereof and, in addition, in the separation step, when the resin substrate is separated from the support substrate, the substrate of the resin substrate in itself is damaged and it becomes difficult to separate with good reproducibility.

Also, in the resin substrate formation step, the birefringence of the resin substrate is specified to be 0.002 or more and 0.1 or less, so that the solvent resistance of the resin substrate is specifically ensured. Here, FIG. 9 is a graph showing the relationship between the birefringence and the film thickness decrease rate of the resin substrate. In this regard, the film thickness decrease rate indicated by the vertical axis in FIG. 9 is the decrease rate of a film thickness (substrate thickness) after the resin substrate is immersed in an organic solvent and serves as an indicator of the solvent resistance. Here, in general, the solvent resistance is in the relationship of trade-off with the birefringence. Therefore, various polyimide resin substrates were formed, the birefringence of each resin substrate was measured using, for example, Retardation Measurement System produced by OTSUKA ELECTRONICS CO., LTD., and in addition, each resin substrate was subjected to a treatment of immersion in an organic solvent (for example, a mixed solution of 2-aminoethanol and dimethyl sulfoxide (percent by weight ratio 70:30), a single solution of dimethyl sulfoxide, or the like) for about 1 hour at 60° C., the film thickness decrease rate was calculated from film thicknesses before and after the treatment of each resin substrate, and the relationship between the birefringence and the film thickness decrease rate of the resin substrate was derived (refer to black circles in the graph shown in FIG. 9). Then, in consideration of the practicality, it is believed that the resin substrate can be washed if the film thickness decrease rate of the solvent resistance is about 3% or less. The birefringence at that time is 0.002 or more in the region surrounded by a thick broken line shown in FIG. 9. In consideration of the practical limit of phase difference compensation, the upper limit thereof is 0.1 or less.

Consequently, in the case where the thickness of the resin substrate is specified to be 5 μm or more and 20 μm or less and, in addition, the birefringence of the resin substrate is specified to be 0.002 or more and 0.1 or less, surface unevenness is suppressed and, in addition, the solvent resistance is ensured with respect to the resin substrate.

### Advantageous Effects of Invention

According to the present invention, the thickness of the resin substrate is 5 μm or more and 20 μm or less and the birefringence of the resin substrate is 0.002 or more and 0.1 or less. Consequently, surface unevenness is suppressed and, in addition, the solvent resistance can be ensured with respect to the resin substrate.

### BRIEF DESCRIPTION OF DRAWINGS

FIG. 1 is a sectional view of a liquid crystal display device according to a first embodiment.

FIG. 2 is a first explanatory diagram of a cross-section showing part of a manufacturing step of the liquid crystal display device according to the first embodiment.

FIG. 3 is a second explanatory diagram of a cross-section showing part of a manufacturing step following the step shown in FIG. 2 of the liquid crystal display device.

FIG. 4 is a third explanatory diagram of a cross-section showing part of a manufacturing step following the step shown in FIG. 3 of the liquid crystal display device.

FIG. 5 is a fourth explanatory diagram of a cross-section showing part of a manufacturing step following the step shown in FIG. 4 of the liquid crystal display device.

FIG. 6 is a fifth explanatory diagram of a cross-section showing part of a manufacturing step following the step shown in FIG. 5 of the liquid crystal display device.

FIG. 7 is a sectional view of a liquid crystal display device according to a second embodiment.

FIG. 8 is a sectional view of a liquid crystal display device according to a third embodiment.

FIG. 9 is a graph showing the relationship between the birefringence and the film thickness decrease rate of a resin substrate.

### DESCRIPTION OF EMBODIMENTS

The embodiments according to the present invention will be described below in detail with reference to the drawings. However, the present invention is not limited to the following individual embodiments.

### First Embodiment According to the Invention

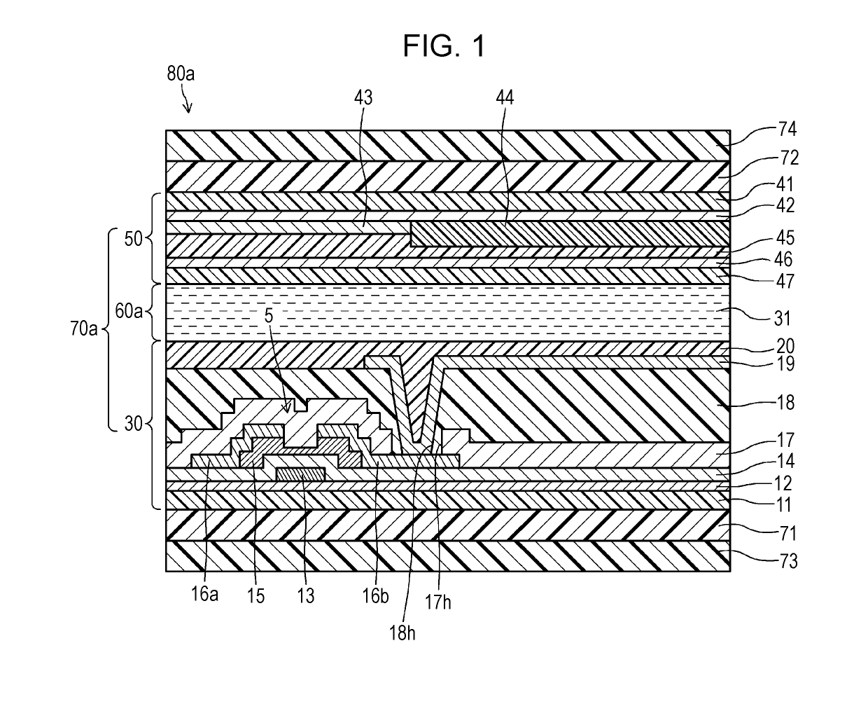

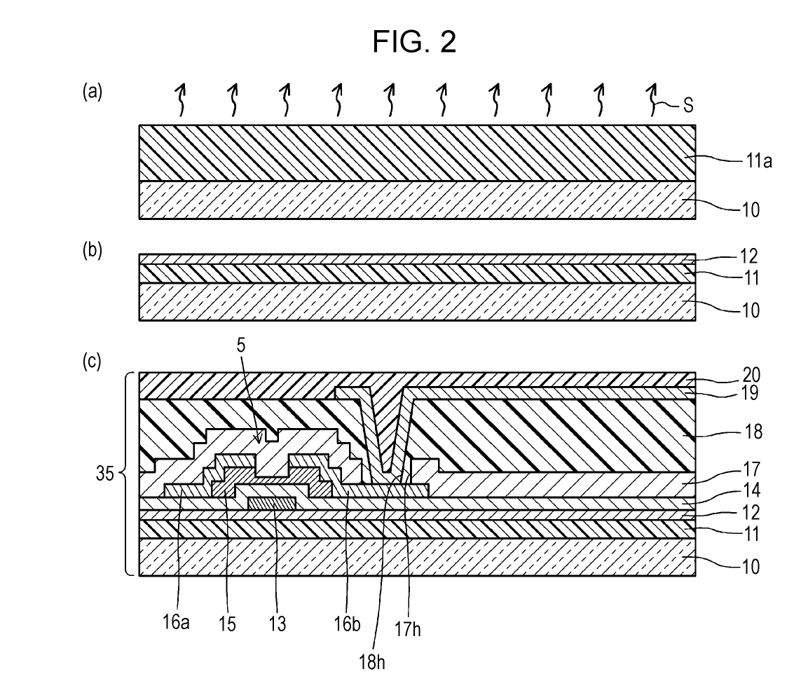

FIG. 1 to FIG. 6 show a first embodiment of a display device and a thin film transistor substrate and a manufacturing method therefor according to the present invention. Specifically, FIG. 1 is a sectional view of a liquid crystal display device 80a according to the present embodiment. Meanwhile, FIG. 2 to FIG. 6 are first to fifth explanatory diagrams of cross-sections showing manufacturing steps of the liquid crystal display device 80a.

As shown in FIG. 1, the liquid crystal display device 80a includes a liquid crystal display panel 70a, a phase difference compensation film 71 disposed on the lower surface of the liquid crystal display panel 70a in the drawing, a polarizing film 73 disposed on the surface of the phase difference compensation film 71, a phase difference compensation film 72 disposed on the upper surface of the liquid crystal display panel 70a in the drawing, and a polarizing film 74 disposed on the surface of the phase difference compensation film 72.

As shown in FIG. 1, the liquid crystal display panel 70a includes a TFT substrate 30 and a counter-substrate 50 which are disposed opposing to each other, a horizontal alignment liquid crystal layer 60a disposed between the TFT substrate 30 and the counter-substrate 50, and a sealant (not shown in the drawing) disposed in the shape of a frame to bond the TFT substrate 30 and the counter-substrate 50 together and, in addition, seal the liquid crystal layer 60a in between the TFT substrate 30 and the counter-substrate 50.

As shown in FIG. 1, the TFT substrate 30 includes a transparent first resin substrate 11 having the heat resistance, a base coating film 12 disposed on the first resin substrate 11, a plurality of gate lines (not shown in the drawing) disposed on the base coating film 12 while extending parallel to each other, a gate insulating film 14 disposed covering the individual gate lines, a plurality of source lines (not shown in the drawing) disposed on the gate insulating film 14 while extending parallel to each other in the direction orthogonal to the individual gate lines, a plurality of TFTs 5 each disposed on an intersection of each gate line and each source line basis, that is, on a subpixel basis, a first interlayer insulating film 17 and a second interlayer insulating film 18 disposed sequentially covering the individual TFTs 5 and the individual source lines, a plurality of pixel electrodes 19 disposed in the matrix on the second interlayer insulating film 18 and connected to the individual TFTs 5, and an alignment film 20 disposed covering the individual pixel electrodes 19.

As shown in FIG. 1, the TFT 5 includes a gate electrode 13 disposed on the first resin substrate 11 with the base coating film 12 therebetween, a gate insulating film 14 disposed covering the gate electrode 13, a semiconductor layer 15 disposed on the gate insulating film 14 while overlapping the gate electrode 13 and taking on an island shape, and a source electrode 16a and a drain electrode 16b disposed on the semiconductor layer 15 while confronting with each other discretely.

The gate electrode 13 is, for example, a portion, which is protruded sideward on a subpixel basis, of each of the above-described gate lines.

The semiconductor layer 15 includes an intrinsic amorphous silicon layer (not shown in the drawing) having a channel region and an n⁺-amorphous silicon layer (not shown in the drawing) disposed on the intrinsic amorphous silicon layer in such a way as to expose the channel region and connected to each of the source electrode 16a and the drain electrode 16b.

The source electrode 16a is, for example, a portion, which is protruded sideward on a subpixel basis, of the above-described source line.

As shown in FIG. 1, the drain electrode 16b is connected to the pixel electrode 19 via a through hole 18h disposed in the second interlayer insulating film 18.

As shown in FIG. 1, the counter-substrate 50 includes a transparent second resin substrate 41 having the heat resistance, a base coating film 42 disposed on the second resin substrate 41, a black matrix 43 disposed in the shape of a lattice on the base coating film 42, a color filter 44 which is a red layer, green layer, blue layer, or the like disposed in the individual lattices of the black matrix 43, a planarizing film 45 disposed covering the black matrix 43 and the color filter 44, a common electrode 46 disposed on the planarizing film 45, and an alignment film 47 disposed covering the common electrode 46.

The first resin substrate 11 and the second resin substrate 41 are made of polyimides, e.g., (wholly) aromatic polyimide, aromatic (carboxylic acid component)-alicyclic (diamine component) polyimide, alicyclic (carboxylic acid component)-aromatic (diamine component) polyimide, (wholly) aliphatic polyimide, and fluorinated aromatic polyimide. Meanwhile, the first resin substrate 11 and the second resin substrate 41 have a thickness of 5 μm to 20 μm and a birefringence of 0.002 to 0.1.

The liquid crystal layer 60a is formed from a nematic liquid crystal material having positive dielectric constant anisotropy or the like.

The liquid crystal display device 80a having the above-described configuration is configured to display an image by applying a predetermined voltage to the liquid crystal layer 60a disposed between each pixel electrode 19 on the TFT substrate 30 and the common electrode 46 on the counter-substrate 50 on a subpixel basis so as to change the alignment state of the liquid crystal layer 60a and adjust thereby the transmittance of light passing through the inside of the liquid crystal display panel 70a on a subpixel basis.

Next, a method for manufacturing the liquid crystal display device 80a according to the present embodiment will be described with reference to FIG. 2 to FIG. 6. Here, the manufacturing method according to the present embodiment includes a first resin substrate formation step, a TFT substrate precursor production step containing a TFT formation step, a second resin substrate formation step, a counter-substrate precursor production step, a panel precursor production step, a first resin substrate separation step, an optical sheet first attachment step, a second resin substrate separation step, and an optical sheet second attachment step.

<First Resin Substrate Formation Step>

Initially, a silane coupling agent is applied to a first support substrate 10, e.g., a glass substrate, by a spin coating method, for example. Thereafter, a silane coupling film (not shown in the drawing) is formed by performing a heat treatment.

Subsequently, a resin solution 11a is applied to the first support substrate 10 provided with the above-described silane coupling film by the spin coating method. Then, as shown in FIG. 2 (a), the first resin substrate 11 is formed by performing a heat treatment, so as to volatilize an organic solvent S from the resin solution 11a and, in addition, induce an imidization reaction. Here, the resin solution 11a is prepared by, for example, dissolving polyamic acid serving as a precursor of polyimide into an organic solvent, e.g., dimethylacetamide or N-methylpyrrolidone. In this regard, as for the heat treatment of the resin solution 11a, for example, the first support substrate 10 coated with the resin solution 11a is placed on a hot plate, heating is performed in the air atmosphere at about 30° C. to 40° C. for about 1 hour and, thereafter, heating is performed in a nitrogen atmosphere at about 250° C. to 350° C. for about 1 hour to 3 hours in order to suppress discoloration to yellow due to oxidation and induce imidization.

<TFT Substrate Precursor Production Step>

Initially, the surface of the first resin substrate 11 formed in the above-described first resin substrate formation step is washed with, for example, an organic solvent e.g., a mixed solution of 2-aminoethanol and dimethyl sulfoxide (percent by weight ratio 70:30), dimethyl sulfoxide, or N-methylpyrrolidone. Thereafter, an inorganic insulating film, e.g., a silicon nitride film or a silicon oxide film, having a thickness of about 50 nm to 500 nm (preferably, 100 nm to 300 nm) is formed on the surface of the first resin substrate 11 by, for example, a plasma CVD (Chemical Vapor Deposition) method, so as to form the base coating film 12, as shown in FIG. 2 (b).

Subsequently, a metal stacked film is formed by forming a titanium film (thickness about 30 nm to 150 nm), an aluminum film (thickness about 200 nm to 500 nm), and a titanium film (thickness about 30 nm to 150 nm) sequentially on the whole substrate provided with the base coating film 12 by, for example, a sputtering method. Then, the metal stacked film is subjected to a photolithography treatment, an etching treatment, and a resist peeling treatment, so as to form the gate electrode 13 and the gate lines.

Furthermore, the gate insulating film 14 is formed by forming a silicon oxide film having a thickness of about 200 nm to 500 nm on the whole substrate provided with the gate electrode 13 and the like by, for example, a plasma CVD method using tetraethoxysilane (TEOS).

Then, an intrinsic amorphous silicon film (thickness about 70 nm to 150 nm) and an n⁺-amorphous silicon film doped with phosphorus (thickness about 40 nm to 80 nm) are formed sequentially on the whole substrate provided with the gate insulating film 14 by, for example, the plasma CVD method. Thereafter, the stacked film of the intrinsic amorphous silicon film and the n⁺-amorphous silicon film is subjected to the photolithography treatment, the etching treatment, and the resist peeling treatment, so as to form a semiconductor layer formation layer.

Subsequently, a metal stacked film is formed by forming, for example, an aluminum film (thickness about 100 nm to 400 nm), a titanium film (thickness about 30 nm to 100 nm), and the like sequentially on the whole substrate provided with the above-described semiconductor layer formation layer by a sputtering method. Then, the metal stacked film is subjected to the photolithography treatment, the etching treatment, and the resist peeling treatment, so as to form the source electrode 16a, drain electrode 16b, and the source lines.

Furthermore, a channel region is formed by etching the n⁺-amorphous silicon film of the above-described semiconductor layer formation layer while the source electrode 16a and the drain electrode 16b are used as masks, so as to form the semiconductor layer 15 and TFT 5 provided therewith (TFT formation step).

In addition, an inorganic insulating film, e.g., a silicon nitride film, having a thickness of about 100 nm to 300 nm is formed on the whole substrate provided with the TFT 5 by, for example, the plasma CVD. The inorganic insulating film is subjected to the photolithography treatment, the etching treatment, and the resist peeling treatment, so as to form the first interlayer insulating film 17 having a via hole 17h reaching the drain electrode 16b.

Subsequently, for example, acrylic photosensitive resin having a thickness of about 2 μm to 3 μm is applied to the whole substrate provided with the first interlayer insulating film 17 by the spin coating method. The resulting photosensitive resin is subjected to exposure and development, so as to form the second interlayer insulating film 18 having the through hole 18h reaching the drain electrode 16b.

Furthermore, a transparent electrically conductive film, e.g., an ITO (Indium Tin Oxide) film, having a thickness of about 100 nm to 200 nm is formed on the whole substrate provided with the second interlayer insulating film 18 by, for example, the sputtering method. Thereafter, the transparent electrically conductive film is subjected to the photolithography treatment, the etching treatment, and the resist peeling treatment, so as to form the pixel electrode 19.

Finally, a polyimide based resin film having a thickness of about 100 nm is applied to the whole substrate provided with the pixel electrode 19 by, for example, the spin coating method. Thereafter, the coating film is subjected to firing and a rubbing treatment, so as to form the alignment film 20.

In this manner, a TFT substrate precursor 35, as shown in FIG. 2 (c), can be produced.

<Second Resin Substrate Formation Step>

Initially, a silane coupling agent is applied to a second support substrate 40, e.g., a glass substrate, by the spin coating method. Thereafter, a silane coupling film (not shown in the drawing) is formed by performing a heat treatment.

Subsequently, a resin solution (not shown in the drawing) is applied to the second support substrate 40 provided with the above-described silane coupling film by the spin coating method as with the above-described first resin substrate formation step. Then, the second resin substrate 41 is formed by performing a heat treatment, so as to volatilize an organic solvent from the resin solution and, in addition, induce an imidization reaction.

<Counter-Substrate Precursor Production Step>

Initially, the surface of the second resin substrate 41 formed in the above-described second resin substrate formation step is washed with, for example, an organic solvent e.g., a mixed solution of 2-aminoethanol and dimethyl sulfoxide, dimethyl sulfoxide, or N-methylpyrrolidone. Thereafter, an inorganic insulating film, e.g., a silicon nitride film or a silicon oxide film, having a thickness of about 50 nm to 500 nm (preferably, 100 nm to 300 nm) is formed on the surface of the second resin substrate 41 by, for example, the plasma CVD method, so as to form the base coating film 42.

Subsequently, a metal film, e.g., a chromium film (thickness about 100 nm), is formed on the whole substrate provided with the base coating film 42 by, for example, the sputtering method. Then, the metal film is subjected to the photolithography treatment, the etching treatment, and the resist peeling treatment, so as to form the black matrix 43.

In addition, a photosensitive resin colored red, green, or blue is applied to the whole substrate provided with the black matrix 43 by, for example, the spin coating method. Thereafter, the coating film is subjected to exposure and development, so as to form a colored layer of a selected color (for example, red) having a thickness of about 1 μm. The same step is repeated with respect to the other two colors and, thereby, colored layers of the other two colors (for example, a green layer and a blue layer) having a thickness of about 1 μm are formed, so as to form the color filter 44.

Subsequently, an acrylic resin having a thickness of about 1 μm is applied to the whole substrate provided with the color filter 44 by, for example, the spin coating method. Thereafter, a planarizing film 45 is formed by performing a heat treatment.

Furthermore, a transparent electrically conductive film, e.g., an ITO film, having a thickness of about 100 nm is formed on the whole substrate provided with the planarizing film 45 by, for example, the sputtering method using a mask, so as to form the common electrode 46.

Finally, a polyimide based resin film having a thickness of about 100 nm is applied to the whole substrate provided with the common electrode 46 by, for example, the spin coating method. Thereafter, the coating film is subjected to firing and a rubbing treatment, so as to form the alignment film 47.

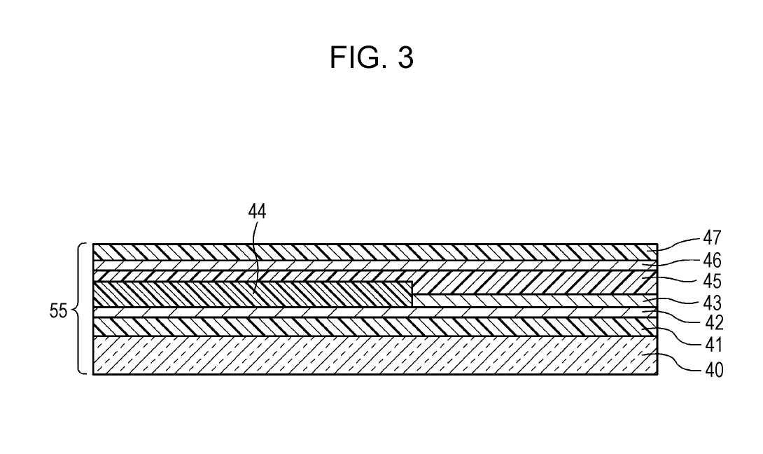

In this manner, the counter-substrate precursor 55, as shown in FIG. 3, can be produced.

<Panel Precursor Production Step>

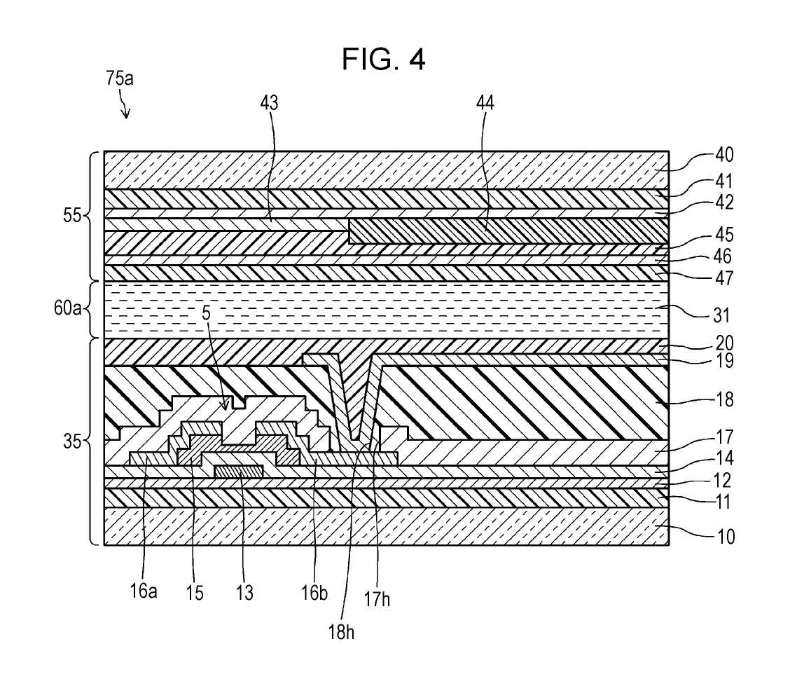

For example, a sealant formed from a thermosetting resin or the like and provided with a liquid crystal injection hole is printed on the surface of the alignment film 47 on the counter-substrate precursor 55 produced in the above-described counter-substrate precursor production step. The resulting counter-substrate precursor 55 printed with the sealant and the TFT substrate precursor 35 produced in the above-described TFT substrate precursor production step are bonded together and the above-described sealant is cured. Thereafter, a liquid crystal material is injected between the TFT substrate precursor 35 and the counter-substrate precursor 55 by a vacuum injection method and, in addition, the above-described liquid crystal injection hole is sealed. Consequently, the liquid crystal layer 60a is sealed in between the TFT substrate precursor 35 and the counter-substrate precursor 55, so that the panel precursor 75a, as shown in FIG. 4, is produced.

<First Resin Substrate Separation Step>

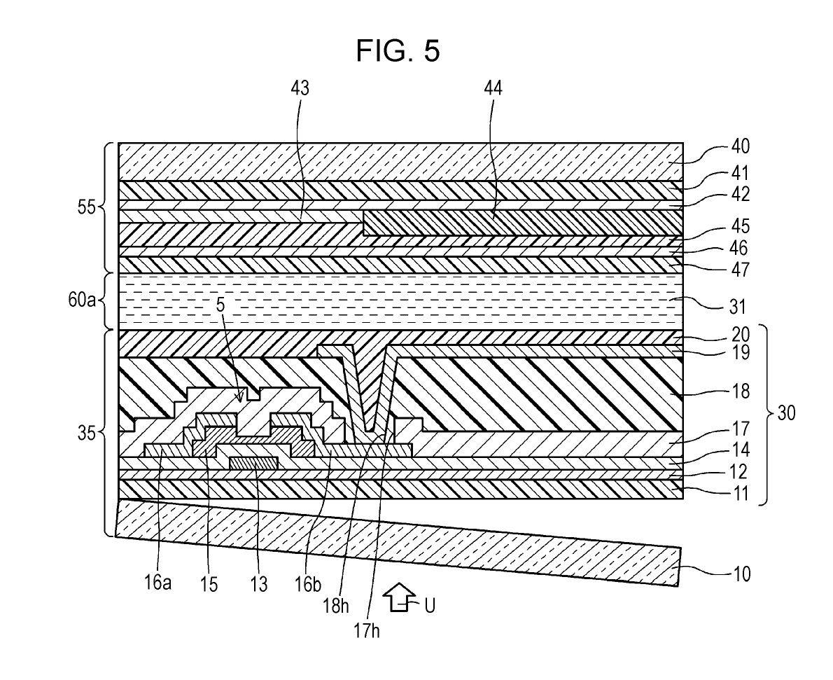

As shown in FIG. 5, the panel precursor 75a produced in the above-described panel precursor production step is irradiated with ultraviolet laser light U from the TFT substrate precursor 35 side and, thereby, ablation (decomposition/vaporization of film due to heat absorption) phenomenon due to absorption of ultraviolet rays occurs in a portion on the first resin substrate 11 side of the boundary portion between the first support substrate 10 and the first resin substrate 11, so that the first support substrate 10 and the first resin substrate 11 are separated. Here, for example, the laser light with a wavelength of 308 nm lased from a XeCl laser is suitable for the ultraviolet laser light U to be applied. Meanwhile, as for the ablation condition, it is necessary that the condition is specified in accordance with the resin substrate to be irradiated. For example, the intensity of irradiation energy is about 300 mW/cm² to 400 mW/cm² and 1 shot to 10 shots of irradiation is performed. In this regard, the transmittance of the ultraviolet laser light U is about 1% or less as for the resin substrate (first resin substrate 11) and about 90% or more as for the glass substrate (support substrate 10).

<Optical Sheet First Attachment Step>

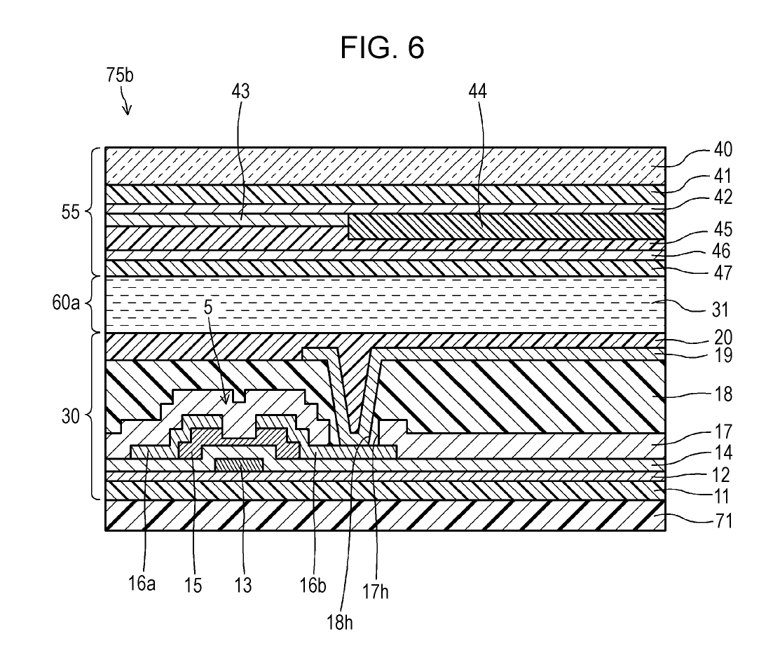

As shown in FIG. 6, the phase difference compensation film 71 is attached to the surface of the TFT substrate 30 constituting the panel precursor 75a, from which the first support substrate 10 has been separated in the above-described first resin substrate separation step.

<Second Resin Substrate Separation Step>

The second support substrate 40 and the second resin substrate 41 are separated by applying the ultraviolet laser light to the panel precursor 75b, to which the phase difference compensation film 71 has been attached in the above-described optical sheet first attachment step, from the counter-substrate precursor 55 side as with the above-described first resin substrate separation step.

<Optical Sheet Second Attachment Step>

After the phase difference compensation film 72 is attached to the surface of the counter-substrate 50 constituting the panel precursor 75b, from which the second support substrate 40 has been separated in the above-described second resin substrate separation step, the polarizing films 73 and 74 are attached to the surfaces of the phase difference compensation films 71 and 72, respectively.

In this manner, the liquid crystal display device 80a according to the present embodiment can be produced.

As described above, according to the TFT substrate 30, the liquid crystal display device 80a including the same, and the method for manufacturing them of the present embodiment, in the first resin substrate formation step and the second resin substrate formation step, the thickness of each of the first resin substrate 11 and the second resin substrate 41 serving as the base substrates of the TFT substrate 30 and the counter-substrate 50 is specified to be 5 μm or more and 20 μm or less. Consequently, generation of bubbles in the coating film of the resin solution 11a is suppressed when the organic solvent S is volatilized, so that surface unevenness of the first resin substrate 11 and the second resin substrate 41 can be suppressed. Here, if the thickness of each of the first resin substrate 11 and the second resin substrate 41 is larger than 20 μm, for example, even when the temperature in volatilization of the organic solvent is lowered to about room temperature to suppress generation of bubbles from the coating film, each of the surfaces of the first resin substrate 11 and the second resin substrate 41 is formed taking on an uneven shape. Meanwhile, in the case where the thickness of each of the first resin substrate 11 and the second resin substrate 41 is smaller than 5 μm, it becomes difficult that the first resin substrate 11 and the second resin substrate 41 maintain the shapes thereof and, in addition, in the separation step, when the first resin substrate 11 and the second resin substrate 41 are separated from the first support substrate 10 and the second support substrate 40, respectively, the first resin substrate 11 and the second resin substrate 41 in themselves are damaged and it becomes difficult to separate with good reproducibility.

Also, in the first resin substrate formation step and the second resin substrate separation step, the birefringence of each of the first resin substrate 11 and the second resin substrate 41 is specified to be 0.002 or more and 0.1 or less, so that the solvent resistance of the first resin substrate 11 and the second resin substrate 41 can be specifically ensured. Here, FIG. 9 is a graph showing the relationship between the birefringence and the film thickness decrease rate of the resin substrate. In this regard, the film thickness decrease rate indicated by the vertical axis in FIG. 9 is the decrease rate of a film thickness (substrate thickness) after the resin substrate is immersed in an organic solvent and serves as an indicator of the solvent resistance. Here, in general, the solvent resistance is in the relationship of trade-off with the birefringence. Therefore, various polyimide resin substrates were formed, the birefringence of each resin substrate was measured using, for example, Retardation Measurement System produced by OTSUKA ELECTRONICS CO., LTD., and in addition, each resin substrate was subjected to a treatment of immersion in an organic solvent (for example, a mixed solution of 2-aminoethanol and dimethyl sulfoxide (percent by weight ratio 70:30), a single solution of dimethyl sulfoxide, or the like) for about 1 hour at 60° C., the film thickness decrease rate was calculated from film thicknesses before and after the treatment of each resin substrate, and the relationship between the birefringence and the film thickness decrease rate of the resin substrate was derived (refer to black circles in the graph shown in FIG. 9). Then, in consideration of the practicality, it is believed that the resin substrate can be washed if the film thickness decrease rate of the solvent resistance is about 3% or less. The birefringence at that time is 0.002 or more in the region surrounded by a thick broken line shown in FIG. 9. In consideration of the practical limit of phase difference compensation, the upper limit thereof is 0.1 or less.

Consequently, in the case where the thickness of each of the first resin substrate 11 and the second resin substrate 41 is specified to be 5 μm or more and 20 μm or less and, in addition, the birefringence of each of the first resin substrate 11 and the second resin substrate 41 is specified to be 0.002 or more and 0.1 or less, surface unevenness is suppressed and, in addition, the solvent resistance is ensured with respect to the first resin substrate 11 and the second resin substrate 41. Then, an occurrence of display variations is suppressed and the degradation in display quality can be suppressed because surface unevenness can be suppressed with respect to the first resin substrate 11 and the second resin substrate 41.

Meanwhile, according to the liquid crystal display device 80a of the present embodiment, the polarizing films 73 and 74 are attached to the outside surface of the TFT substrate 30 and the outside surface of the counter-substrate 50, respectively. Therefore, the TFT substrate 30 and the counter-substrate 50 can be reinforced by the strength of the polarizing films 73 and 74 in themselves.

Also, according to the liquid crystal display device 80a, the phase difference compensation films 71 and 72 which function as the positive C plates (the refractive indices nₓ and n_{y} in the in-plane direction of the substrate are smaller than the refractive index n_{z} in the direction perpendicular to the substrate, that is, nₓ=n_{y}<n_{z}) are disposed in between the TFT substrate 30 and the polarizing film 73 and between the counter-substrate 50 and the polarizing film 74, respectively. Therefore, phase differences due to the birefringence of the first resin substrate 11 and the second resin substrate 41 which function as negative C plates (the refractive indices nₓ and n_{y} in the in-plane direction of the substrate are larger than the refractive index n_{z} in the direction perpendicular to the substrate, that is, nₓ=n_{y}>n_{z}) are compensated and, in addition, the TFT substrate 30 and the counter-substrate 50 can be further reinforced by the strength of the phase difference compensation films 71 and 72 in themselves.

Also, according to the liquid crystal display device 80a of the present embodiment, in the case where the first resin substrate 11 and the second resin substrate 41 are made of alicyclic polyimide and intramolecular and intermolecular charge-transfer complexes are not formed or are made of fluorinated aromatic polyimide and intramolecular and intermolecular charge-transfer complexes are not formed easily because of a fluorine-containing structure, the transparency in the visible light region becomes good and colorless, transparent first resin substrate 11 and second resin substrate 41 can be obtained.

Also, according to the method for manufacturing the liquid crystal display device 80a of the present embodiment, the optical sheet first attachment step is included between the first resin substrate separation step and the second resin substrate separation step. Consequently, even when the first resin substrate separation step is performed and the first resin substrate 11 becomes about 5 μm to 20 μm and, therefore, thin, the shape can be maintained stably by the support substrate 40 on the second resin substrate 41 side.

Also, according to the liquid crystal display device 80a of the present embodiment, the thicknesses of the first resin substrate 11 and the second resin substrate become small and the phase difference (=birefringence×film thickness) due to the effective birefringence becomes small. Consequently, the range of selection of the material for constituting the resin substrate can be increased with respect to the birefringence.

Also, according to the method for manufacturing the liquid crystal display device 80a of the present embodiment, the TFT 5 can be formed by a high-yield TFT production process including a step to wash the substrate surface by using an organic solvent for removing particles. Consequently, the liquid crystal display device 80a having high quality and high reliability can be produced at a high proportion of acceptable products.

Also, according to the method for manufacturing the liquid crystal display device 80a of the present embodiment, even the liquid crystal display device 80a including the resin substrate can use already available TFT production apparatus and TFT production process, in which a glass substrate is used. Therefore, a new investment is suppressed and a device including the resin substrate can be provided at a low cost.

### Second Embodiment According to the Invention

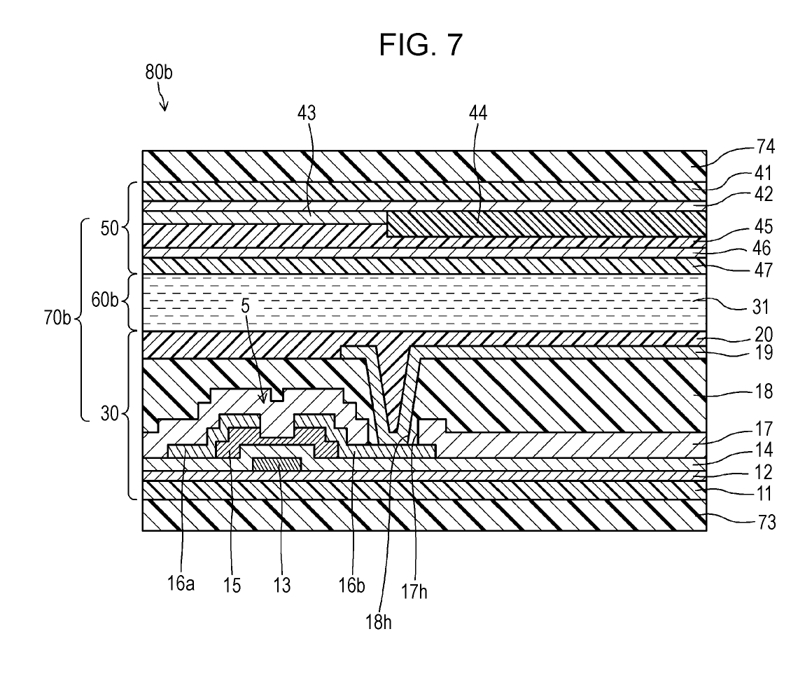

FIG. 7 is a sectional view of a liquid crystal display device 80b according to the present embodiment. Meanwhile, in each embodiment described below, the same portions as those in FIG. 1 to FIG. 6 are indicated by the same reference numerals as those set forth above and further explanations thereof will not be provided.

In the above-described first embodiment, the liquid crystal display device 80a including a horizontal alignment liquid crystal layer 60a has been shown as an example. In the present embodiment, the liquid crystal display device 80b including a vertical alignment liquid crystal layer 60b is shown as an example.

Specifically, as shown in FIG. 7, the liquid crystal display device 80b includes a liquid crystal display panel 70b, a polarizing film 73 on the lower surface of the liquid crystal display panel 70b in the drawing, and a polarizing film 74 disposed on the upper surface of the liquid crystal display panel 70b in the drawing.

As shown in FIG. 7, the liquid crystal display panel 70b includes a TFT substrate 30 and a counter-substrate 50 which are disposed opposing to each other, a vertical alignment liquid crystal layer 60b disposed between the TFT substrate 30 and the counter-substrate 50, and a sealant (not shown in the drawing) disposed in the shape of a frame to bond the TFT substrate 30 and the counter-substrate 50 together and, in addition, seal the liquid crystal layer 60b in between the TFT substrate 30 and the counter-substrate 50.

The liquid crystal layer 60b is formed from a nematic liquid crystal material having negative dielectric constant anisotropy or the like.

The liquid crystal display device 80b having the above-described configuration is configured to display an image by applying a predetermined voltage to the liquid crystal layer 60b disposed between each pixel electrode 19 on the TFT substrate 30 and the common electrode 46 on the counter-substrate 50 on a subpixel basis so as to change the alignment state of the liquid crystal layer 60b and adjust thereby the transmittance of light passing through the inside of the liquid crystal display panel 70b on a subpixel basis.

The liquid crystal display device 80b can be produced by changing the liquid crystal material injected in the panel precursor production step and, in addition, omitting the optical sheet first attachment step and attaching only the polarizing films 73 and 74 without attaching the phase difference compensation film 72 in the optical sheet second attachment step in the manufacturing method explained in the above-described first embodiment.

As described above, according to the TFT substrate 30, the liquid crystal display device 80a including the same, and the method for manufacturing them of the present embodiment, as with the above-described first embodiment, the thickness of each of the first resin substrate 11 and the second resin substrate 41 is specified to be 5 μm or more and 20 μm or less and, in addition, the birefringence of each of the first resin substrate 11 and the second resin substrate 41 is specified to be 0.002 or more and 0.1 or less. Therefore, surface unevenness is suppressed and, in addition, the solvent resistance can be ensured with respect to the first resin substrate 11 and the second resin substrate 41.

Meanwhile, according to the liquid crystal display device 80b of the present embodiment, the vertical alignment liquid crystal layer 60b sealed in between the TFT substrate 30 and the counter-substrate 50 functions as a positive C plate. Therefore, (a phase difference due to) the birefringence of the first resin substrate 11 and the second resin substrate 41 which function as negative C plates is compensated without disposing a phase difference compensation film separately. Here, in order to obtain good display characteristics, it becomes necessary to compensate a phase difference of about 275 nm which is a phase difference corresponding to one-half the wavelength of green (550 nm) with the highest luminosity factor of a human in general. Then, if the assumption is made that the vertical alignment liquid crystal layer 60b functioning as a positive C plate is compensated evenly by the first resin substrate 11 on the TFT substrate 30 side and the second resin substrate 41 on the counter-substrate 50 side, each side may compensate a phase difference of 137.5 nm (=275 nm/2). However, the polarizing films 73 and 74 attached to the outside surface of the TFT substrate 30 and the outside surface of the counter-substrate 50, respectively, function as the negative C plates. In consideration of the fact that phase differences due to the birefringence of the polarizing films 73 and 74 are about several nanometers to 30-odd nanometers, the amount of compensation of phase difference by each of the first resin substrate 11 and the second resin substrate 41 becomes about 100 nm to 137.5 nm. Then, on the basis of the relationship, Δn·d (film thickness)=phase difference, when the film thicknesses of the first resin substrate 11 and the second resin substrate 41 are 5 μm to 20 μm, the corresponding Δn (birefringence) becomes 0.005 to 0.027. Consequently, in the case where the birefringence of each of the first resin substrate 11 and the second resin substrate 41 is 0.005 to 0.027, the birefringence falls within the range taking the solvent resistance into consideration (0.002 to 0.1), so that the solvent resistance of each of the first resin substrate 11 and the second resin substrate 41 can also be ensured.

Also, according to the liquid crystal display device 80b of the present embodiment, a phase difference compensation film is not disposed. Therefore, the thickness of the liquid crystal display device 80b can be decreased. Furthermore, the members used are decreased, so that a unit cost of production can be reduced to a low level and, in addition, the number of production steps can be decreased.

### Third Embodiment According to the Invention

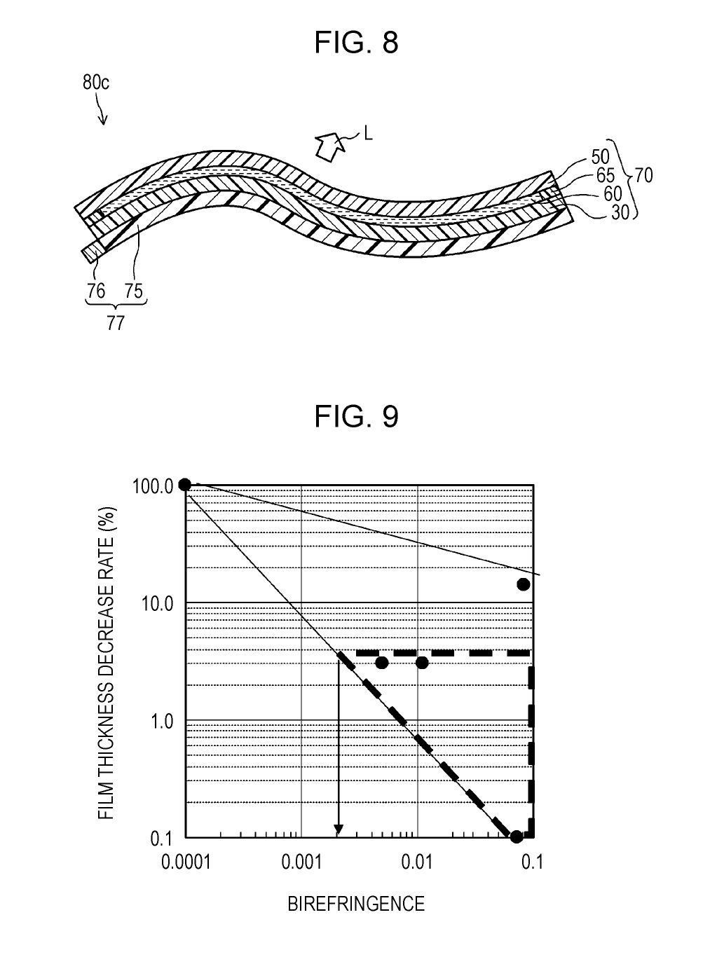

FIG. 8 is a sectional view of a liquid crystal display device 80c according to the present embodiment.

In each of the above-described embodiments, planar liquid crystal display devices 80a and 80b have been shown as examples. In the present embodiment, a flexible curved surface-shaped liquid crystal display device 80c is shown as an example.

Specifically, as shown in FIG. 8, the liquid crystal display device 80c includes a liquid crystal display panel 70 and a backlight 77 disposed under the liquid crystal display panel 70 in the drawing. Meanwhile, in FIG. 8, optical sheets (a polarizing film, a phase difference compensation film, and the like) attached to the surface and the back of the liquid crystal display panel 70 are omitted.

As shown in FIG. 8, the liquid crystal display panel 70 includes a TFT substrate 30 and a counter-substrate 50 which are disposed opposing to each other, a liquid crystal layer 60 disposed between the TFT substrate 30 and the counter-substrate 50, and a sealant 65 disposed in the shape of a frame to bond the TFT substrate 30 and the counter-substrate 50 together and, in addition, seal the liquid crystal layer 60 in between the TFT substrate 30 and the counter-substrate 50. Here, the liquid crystal layer 60 is the liquid crystal layer 60a in the above-described first embodiment or the liquid crystal layer 60b in the above-described second embodiment.

As shown in FIG. 8, the backlight 77 includes a flexible light-guide plate 75 which is deformed in accordance with the shape of the liquid crystal display panel 70, a plurality of light sources 76 disposed along one side (a left end in the drawing) of the light-guide plate 75, and a reflection sheet (not shown in the drawing) which is disposed on the lower surface of the light-guide plate 75 in the drawing and which reflects light from each of the light sources 76 to the liquid crystal display panel 70 side. Here, the light-guide plate 75 is formed from, for example, transparent silicone rubber. Meanwhile, the light source 76 is formed from, for example, Light Emitting Diode (LED). Here, optical sheets, e.g., a diffusion sheet and a lens sheet, may be disposed between the TFT substrate 30 and the light-guide plate 75.

The liquid crystal display device 80c having the above-described configuration is configured to display an image by applying a predetermined voltage to the liquid crystal layer 60 disposed between each pixel electrode 19 on the TFT substrate 30 and the common electrode 46 on the counter-substrate 50 on a subpixel basis so as to change the alignment state of the liquid crystal layer 60 and adjust thereby the transmittance of light passing through the inside of the liquid crystal display panel 70 on a subpixel basis and, thereafter, emitting display light L, as shown in FIG. 8.

As described above, according to the TFT substrate 30 and the liquid crystal display device 80c including the same of the present embodiment, as with the above-described first and second embodiments, the thickness of each of the first resin substrate 11 and the second resin substrate 41 is specified to be 5 μm or more and 20 μm or less and, in addition, the birefringence of each of the first resin substrate 11 and the second resin substrate 41 is specified to be 0.002 or more and 0.1 or less. Therefore, surface unevenness is suppressed and, in addition, the solvent resistance can be ensured with respect to the first resin substrate 11 and the second resin substrate 41.

Meanwhile, in each of the above-described embodiments, the liquid crystal display device has been shown as an example of the display device. However, the present invention can also be applied to a spatial light modulation element (a parallel information processing optical computing system and the like) through the use of polarization of light by using, for example, a material having an electrooptic effect (for example, KDP (KH₂PO₄) crystal, LiTaO₃, LiNbO₃, Ba₂NaNb₅O₁₅, and Sr_{0.5}Ba_{0.5}Nb₂O₆) instead of a liquid crystal material.

Also, in each of the above-described embodiments, the TFT substrate, in which the TFT electrode connected to the pixel electrode is specified to be the drain electrode, has been shown as an example. However, the present invention can also be applied to a TFT substrate, in which a TFT electrode connected to the pixel electrode is referred to as a source electrode.

### INDUSTRIAL APPLICABILITY

As described above, the present invention is useful with respect to a display device including a resin substrate because surface unevenness of the resin substrate can be suppressed and, in addition, the solvent resistance can be ensured.

### REFERENCE SIGNS LIST

S organic solvent
5 TFT
10 first support substrate
11 first resin substrate
11a resin solution
30 TFT substrate
40 second support substrate
41 second resin substrate
50 counter-substrate
60, 60a, 60b liquid crystal layer
71, 72 phase difference compensation film
73, 74 polarizing film
80a to 80c liquid crystal display device

1. (canceled)

2. A method for manufacturing a thin film transistor substrate including
a transparent resin substrate having heat resistance, and
a plurality of thin film transistors disposed on the resin substrate,
the method comprising the steps of:
forming the resin substrate to have a thickness of 5 μm or more and 20 μm or less and a birefringence of 0.002 or more and 0.1 or less by supplying a resin solution to a support substrate and, thereafter, heating the support substrate so as to volatilize an organic solvent from the resin solution;
forming each of the plurality of thin film transistors on the resin substrate formed in the step of forming; and
separating the support substrate from the resin substrate on which the plurality of thin film transistors are disposed.

3. The method of claim 2, further comprising, after the step of separating the support substrate from the resin substrate, the steps of:
attaching a phase difference compensation film to a surface of the resin substrate opposite a surface thereof on which the plurality of thin film transistors are disposed; and
attaching a polarizing film to a surface of the phase difference compensation film.

4. The method of claim 2, wherein
in the step of the separating the support substrate from the resin substrate,
the support substrate is separated from the resin substrate on which the plurality of thin film transistors are disposed by applying ultraviolet rays.

5. The method of claim 2, wherein
in the step of the separating the support substrate from the resin substrate,
the support substrate is separated from the resin substrate on which the plurality of thin film transistors are disposed by applying ultraviolet laser light.

6. The method of claim 5, wherein
an intensity of irradiation energy of the ultraviolet laser light is about 300 mW/cm² to 400 mW/cm².

7. The method of claim 2, wherein
the resin substrate is made of polyimide.
